(19) United States
(12) Patent Application Publication
(10) Pub. No.: US 2005/0189626 A1
(43) Pub. Date: Sep. 1, 2005

(54) Semiconductor device support structures

(76) Inventors: Tan Xiaochun, Shanghai (CN); Shi Jingping, Shanghai (CN)

Correspondence Address: Shemwell Gregory & Courtney LLP, Suite 201, 4880 Stevens Creek Blvd, San Jose, CA, 95129, US

(21) Appl. No.: 11/048,460

(22) Filed: Jan. 31, 2005

Related U.S. Application Data
(60) Provisional application No. 60/540,194, filed on Jan. 29, 2004.

(51) Int. Cl. H01L 23/495

(52) U.S. Cl. 257/666

(57) ABSTRACT

A semiconductor device is provided that includes a platform having an interior surface and an exterior conductive surface. The exterior conductive surface includes an indentation or notch in a portion of one or more edges. The device also includes a die that electrically couples to the interior surface of the platform, along with one or more clips that couple a conductive area of the die to one or more conductive leads. A package enclosure encapsulates the interior surface of the platform, the die, the clip, and portions of the conductive lead. The package enclosure engages the indentation in the exterior conductive surface and secures the package enclosure to the platform.

### RELATED APPLICATION

This application claims the benefit of U.S. patent application Ser. No. 60/540,194, filed on Jan. 29, 2004.

### TECHNICAL FIELD

The present invention relates to support structures and packages for semiconductor devices that include, for example, power elements.

### BACKGROUND

Integrated circuit (“IC”) die or “die” are typically mounted in or on a package in order to form a semiconductor device, also referred to as a “semiconductor device package”, a “semiconductor chip package”, a “semiconductor package” or an “IC device package”. Mounting of an IC die to a package facilitates subsequent attachment of the resulting semiconductor device to a printed circuit board (“PCB”) or other component of an electronic assembly. U.S. Pat. No. 6,608,373 describes a support structure for a semiconductor device including a power element. The support structure includes a conductive mounting platform positioned between two sides of a lead frame. The conductive mounting platform includes an interior conductive surface, an exterior conductive surface, and two envelope engaging members. The interior conductive surface and the area between the envelope engaging members are configured to receive a semiconductor die, and the semiconductor die couples to the interior conductive surface.

The envelope engaging members are preformed to include bends so that the engaging members form an envelope structure that converges as a shell around portions of the semiconductor die and the interior conductive surface. The envelope engaging members, however, can be the cause of stress on the semiconductor device during the process of manufacturing the semiconductor device. Stress placed on the semiconductor device can result in cracking of the semiconductor die and subsequent failure of the semiconductor device. Die cracking and device failures reduce the production quality of the semiconductor devices and increase the costs of production.

### BRIEF DESCRIPTION OF THE FIGURES

FIG. 1 is a schematic diagram of a semiconductor support structure for use in a semiconductor device, under an embodiment.

FIG. 2 is a schematic diagram of a bottom view of the conductive mounting platform, under the embodiment of FIG. 1.

FIG. 3 is a schematic diagram of a top view of a conductive mounting platform, under the embodiment of FIG. 1.

FIG. 4 is a detailed schematic diagram of a conductive mounting platform, under an embodiment.

FIG. 5 is an exploded diagram of the semiconductor device including the conductive mounting platform and a semiconductor die, under an embodiment.

FIG. 6 is a diagram of the semiconductor device, under the embodiment of FIG. 5.

FIG. 7 is a detailed schematic diagram of a clip having a first clip configuration, under an embodiment.

FIG. 8 is a detailed schematic diagram of a clip having a second clip configuration, under an alternative embodiment.

FIG. 9 is a detailed schematic diagram of a conductive mounting platform for use with dual clips, under an alternative embodiment.

FIG. 10 is a detailed schematic diagram of a clip having a dual clip configuration, under an embodiment.

FIG. 11 is a schematic diagram of a semiconductor package including the semiconductor device enclosed in a package enclosure, under an embodiment.

FIG. 12 is a cross-section of the semiconductor device including the semiconductor device, under an embodiment.

FIG. 13 is a bottom perspective view of the semiconductor package that includes the semiconductor device, under an embodiment.

FIG. 14 is a flow diagram for manufacturing a semiconductor device, under an embodiment.

FIG. 15 is a flow diagram for manufacturing a semiconductor device, under an alternative embodiment.

In the drawings, the same reference numbers identify identical or substantially similar elements or acts.

### DETAILED DESCRIPTION

A semiconductor device is provided that includes a platform having an interior surface and an exterior conductive surface. The exterior conductive surface includes an indentation or notch in a portion of one or more edges. The device also includes a die that electrically couples to the interior surface of the platform, along with one or more clips that couple a conductive area of the die to one or more conductive leads. A package enclosure encapsulates the interior surface of the platform, the die, the clip, and portions of the conductive lead. The package enclosure engages the indentation in the exterior conductive surface and secures the package enclosure to the platform.

The semiconductor device of an embodiment includes a support structure including one or more notches or indentations in at least one area of the platform. The one or more notches or indentations are used for engaging the package enclosure of the semiconductor device, also referred to as the packaging enclosure, the packaging material, or packing envelope, thereby simplify manufacturing of the semiconductor device and reducing or eliminating instances of die cracking.

The following description provides specific details for a thorough understanding of, and enabling description for, embodiments of semiconductor device support structures and the methods for making the same (collectively referred to herein as “semiconductor device support structures”). However, one skilled in the art will understand that the semiconductor device support structures described herein may be practiced without these details. In other instances, well-known structures and functions have not been shown or described in detail to avoid unnecessarily obscuring the description of the embodiments of the semiconductor device support structures.

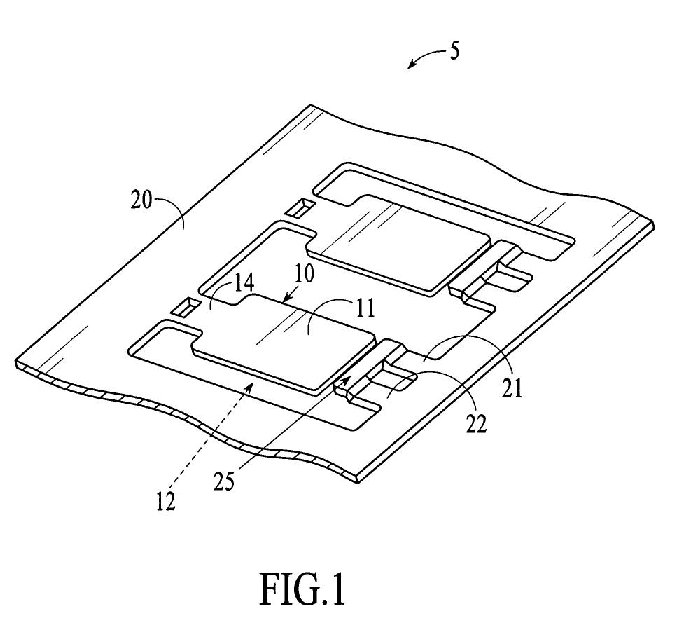

FIG. 1 is a schematic diagram of a semiconductor support structure 5 for use in a semiconductor device, under an embodiment. The semiconductor support structure 5, also referred to as the support structure 5, includes a conductive mounting platform 10 and a lead frame 20. The conductive mounting platform 10 is formed using conductive materials and includes an interior conductive surface 11 and an exterior conductive surface 12.

The support structure 5 also includes a connecting element 14 between a first side of the lead frame 20 and the conductive mounting platform 10. A second side of the lead frame 20 includes two conductive leads 21 and 22. The lead frame 20 of an embodiment is approximately 15 mils (0.015 inches) thick, but is not so limited. The lead frame thickness in combination with the connecting element 14 provides enough strength to the lead frame so as to prevent deformation of the lead frame during the die attach process. Further, the lead frame thickness in combination with the connecting element 14 eliminates the use of tie bars between the sides of the conductive mounting platform 10 and the lead frame. Elimination of the tie bars eliminates a potential entry point for moisture into the semiconductor device.

The conductive leads 21 and 22 can be connected 25 to form a single lead or path between the conductive mounting platform 10 and the lead frame 20. Each conductive lead 21 and 22 includes a first end 25 and a second end 21/22. The second end 21/22 lies in the same plane with the lead frame 20, but is not so limited. The conductive leads 21 and 22 of one or more alternative embodiments may be divided (via a void or break in connector 25) to form separate leads or paths between the conductive mounting platform 10 and the lead frame 20, but are not so limited.

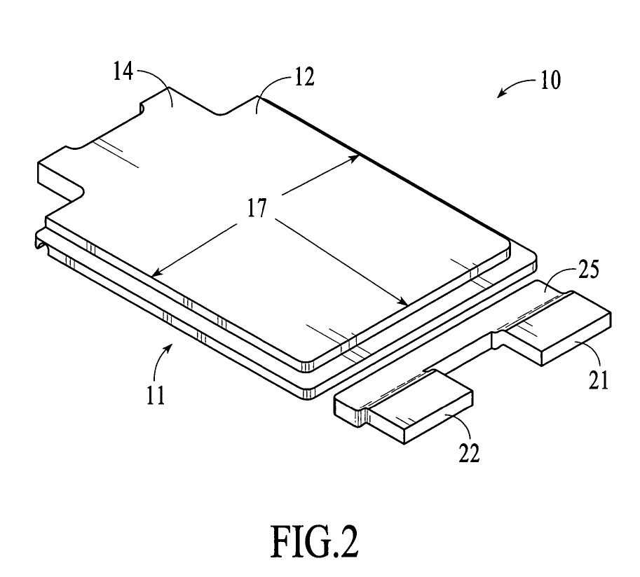

FIG. 2 is a schematic diagram of a bottom view of the conductive mounting platform 10, under the embodiment of FIG. 1. The conductive mounting platform 10 of an embodiment includes at least one indentation or notch structure 17 in the exterior conductive surface 12. The indentation is a notch, recess, or step in a portion of an edge of the conductive mounting platform 10. The indentation receives or engages a portion of the package enclosure and secures the enclosure to the platform.

The conductive mounting platform 10 of an embodiment includes an indentation in a portion or region of three the external edges of the conductive mounting platform 10, but is not so limited. Thus, various alternative embodiments may include the indentation in portions or all of one or more edges of the conductive mounting platform 10 as appropriate to the semiconductor design. As an example, an alternative embodiment may include indentations in less than an entire length of an external edge of the conductive mounting platform. The conductive mounting platform of another alternative embodiment may include indentations in some portion of two opposing edges of the conductive mounting platform.

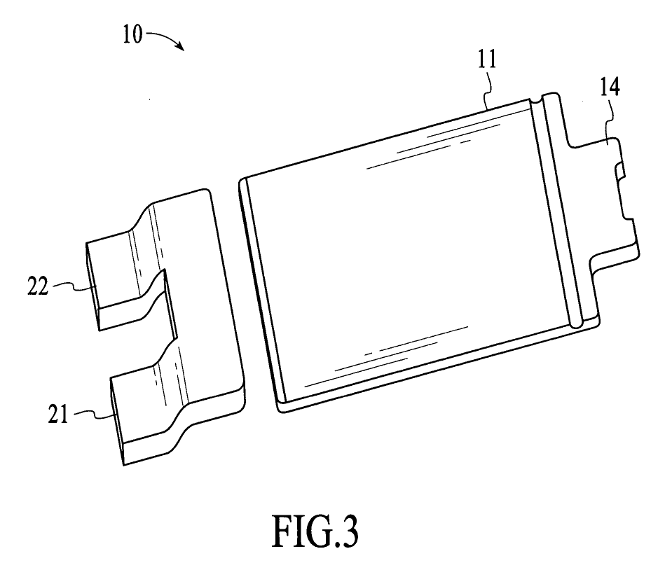

FIG. 3 is a schematic diagram of a top view of a conductive mounting platform 10, under the embodiment of FIG. 1. The conductive mounting platform 10 is formed to include conductive materials and includes an interior conductive surface 11 and an exterior conductive surface (not shown). A connecting element 14 couples the platform 10 to a lead frame (not shown) as described above. The semiconductor structure also includes conductive leads 21 and 22.

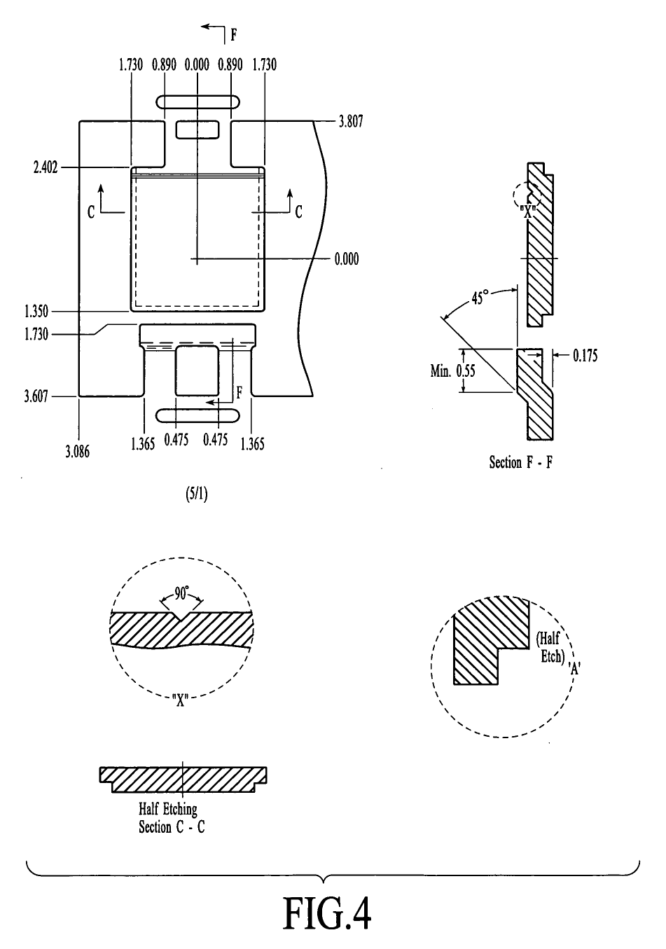

FIG. 4 is a detailed schematic diagram of a conductive mounting platform 10, under an embodiment. The dimensions shown are in millimeters (mm). All tolerances are ±0.05 unless otherwise specified. The material is CDA 194 half hard of thickness 0.381±0.008 mm. The radius on all corners is 0.235 maximum unless otherwise specified. The lead tilt is 0±1.5 degrees. The lead twist is a maximum of 2.5 degrees. The lead tip flat width is 0.2 mm minimum. The die pad flatness is maximum 0.01/2.54. The die pad tilt is maximum 0.025/2.54. The allowed maximum dimensional defects are as follows: cross bow 0.25; strip twist 0.381; camber 0.1. Upset height is to be measured via section F-F direction. The dimensions shown represent the lead frame shape after stamping but before coining operation of coined area. The burr requirement after stamping includes: coin area vertical burr free; vertical burr maximum 0.025; horizontal burr maximum 0.05; burr up.

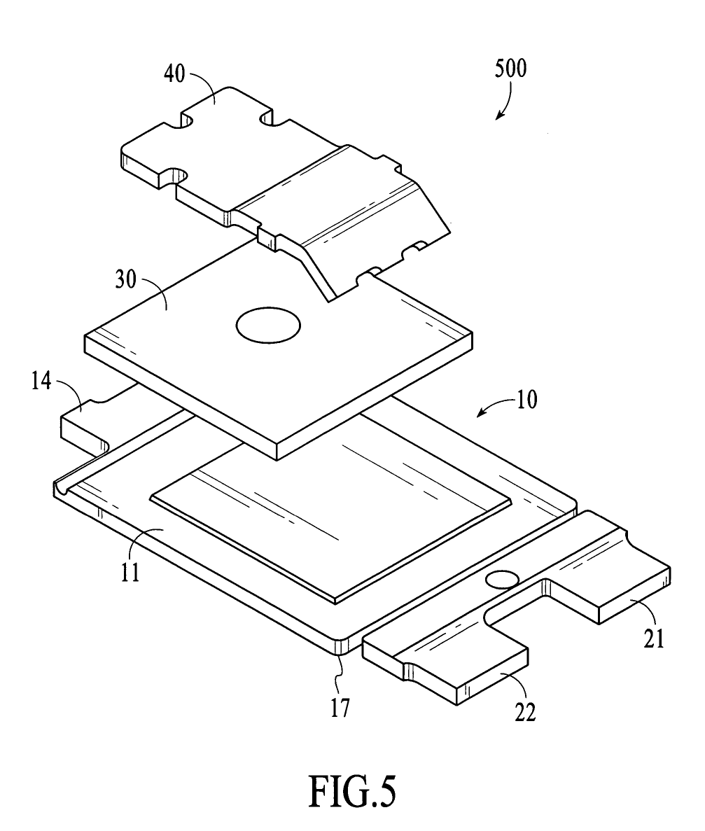

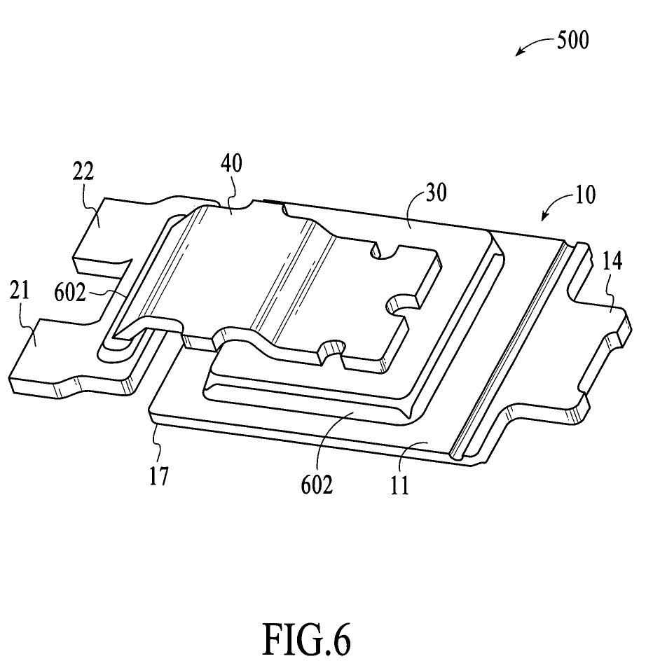

FIG. 5 is an exploded diagram of the semiconductor device 500 including conductive mounting platform 10 and a semiconductor die 30, under an embodiment. FIG. 6 is a diagram of the semiconductor device 500, under the embodiment of FIG. 5. The semiconductor device 500 includes a semiconductor die 30 coupled to the conductive mounting platform 10 using at least one material that includes solder 602, for example. The first ends of the conductive leads 21 and 22 are coupled to the semiconductor die 30 using at least one clip 40 (also referred to herein as “crossing wire 40”). The clip 40, which in one embodiment includes conductive materials, is coupled to the leads 21 and 22 using at least one material that includes solder 602. The path formed between the conductive leads 21 and 22 and the semiconductor die 30 is an electrically conductive path, but is not so limited. The solder 602 of an embodiment may include Microbond Soft Solder Paste PbSn2Ag2,5-D3-DA451-7 for example, but is not so limited.

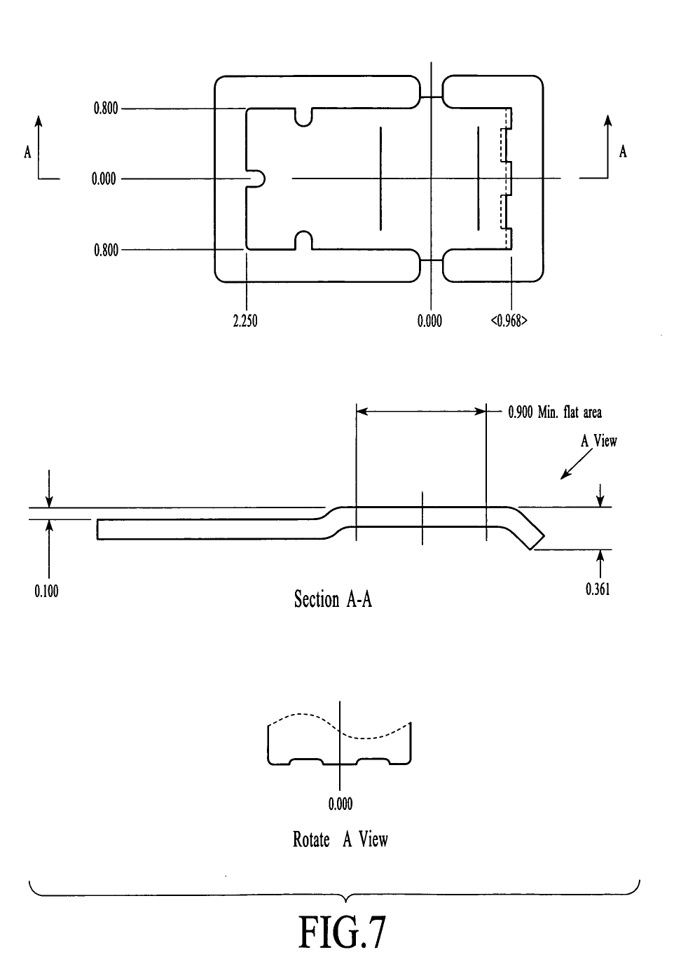

As described above, the semiconductor device 500 includes a lead frame on which the bottom side of a semiconductor die or chip is mounted, along with one or more clips 40 that couple or connect the top side of a semiconductor die to a conductive region (e.g., conductive leads 21 and 22) of the lead frame. The semiconductor device 500 of an embodiment includes a single clip 40, where the single clip 40 may have one or more configurations. FIG. 7 is a detailed schematic diagram of a clip 40 having a first clip configuration 40-1, under an embodiment. The first clip configuration 40-1 is for use in a semiconductor device that includes conductive mounting platform 10 (FIG. 4), but is not so limited. The dimensions shown are in millimeters (mm). All tolerances are ±0.05 unless otherwise specified. The material is CDA 194FH, with thickness 0.152±0.008 mm. The twist over the strip length of the lead frame should not exceed 0.381. The camber over the strip length of the lead frame should not exceed 0.05. The coil-set over the strip length of the lead frame should not exceed 0.50. The crossbow over the width of the lead frame should not exceed 0.20. The vertical burr maximum is 0.03 mm. The horizontal burr maximum is 0.03.

Numerous semiconductor die may be used in the semiconductor device 500 that includes a single clip 40 having the first clip configuration 40-1. As an example, the semiconductor device 500 may include a 110 mil single anode die like the S9404K Schottky Die available from FabTech Incorporated. As an alternative example, the semiconductor device 500 may include a 103 mil single anode die like the S7806K Schottky Die available from FabTech Incorporated.

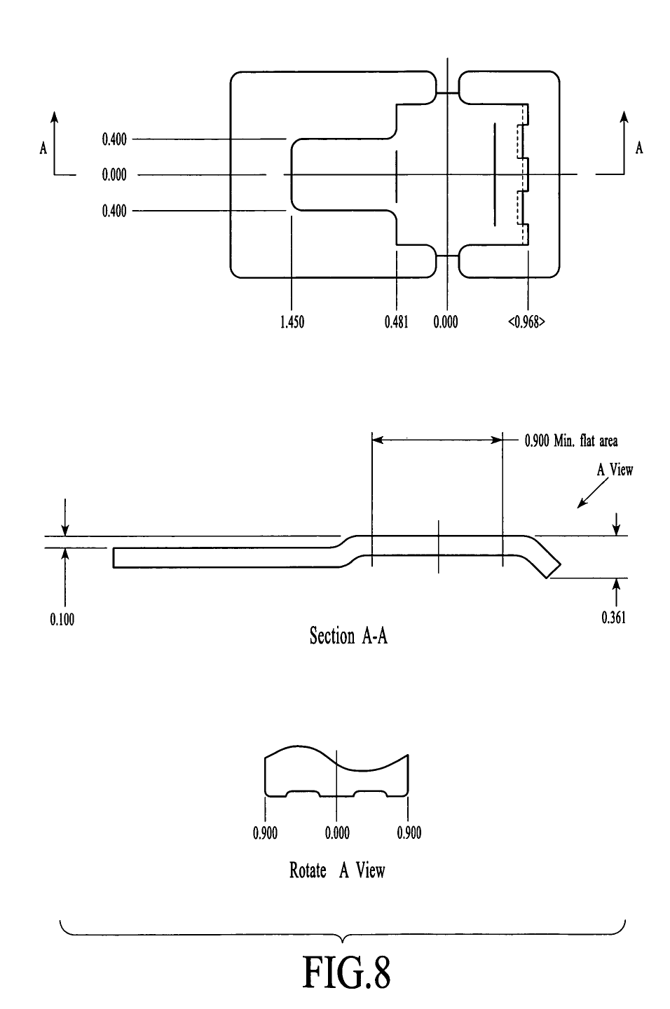

The semiconductor device 500 of an embodiment includes a single clip 40, where the single clip 40 may have a second clip configuration 40-2. FIG. 8 is a detailed schematic diagram of a clip having a second clip configuration 40-2, under an alternative embodiment. The second clip configuration 40-2 is for use in a semiconductor device that includes conductive mounting platform 10 (FIG. 4), but is not so limited. The dimensions shown are in millimeters (mm). All tolerances are ±0.05 unless otherwise specified. The material is CDA 194FH, with thickness 0.152±0.008 mm. The twist over the strip length of the lead frame should not exceed 0.381. The camber over the strip length of the lead frame should not exceed 0.05. The coil-set over the strip length of the lead frame should not exceed 0.50. The crossbow over the width of the lead frame should not exceed 0.20. The vertical burr maximum is 0.03 mm. The horizontal burr maximum is 0.03.

Numerous semiconductor die may be used in the semiconductor device 500 that includes a single clip 40 having the second clip configuration 40-2. As an example, the semiconductor device 500 may include a 63 mil single anode die like the S9140K Schottky Die available from FabTech Incorporated.

As described above, the semiconductor device 500 includes a lead frame on which the bottom side of a semiconductor die or chip is mounted, along with one or more clips 40 that couple or connect the top side of a semiconductor die to a conductive region (e.g., conductive leads 21 and 22) of the lead frame. The semiconductor device 500 of an embodiment includes a conductive mounting platform 10 for use with dual clips 40. When using dual clips, a first clip couples the conductive region of the die to a first conductive lead and a second clip couples the conductive region of the die to a second conductive lead, but the embodiment is not so limited.

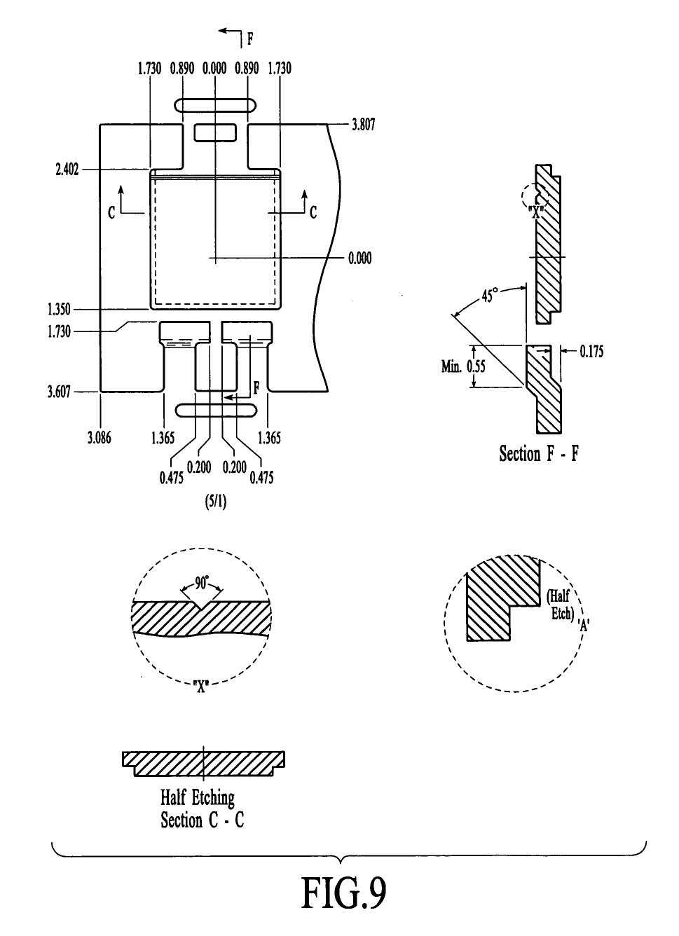

FIG. 9 is a detailed schematic diagram of a conductive mounting platform 10A for use with dual clips, under an alternative embodiment. The dimensions shown are in millimeters (mm). All tolerances are ±0.05 unless otherwise specified. The material is CDA 194 half hard, with thickness 0.381±0.008 mm. The radius on all corners is 0.235 maximum unless otherwise specified. The lead tilt is 0±1.5 degree. The lead twist is a maximum of 2.5 degrees. The lead tip flat width is minimum 0.2 mm. The die pad flatness is maximum 0.01/2.54. The die pad tilt is maximum 0.025/2.54. The allowed maximum dimensional defects are as follows: cross bow 0.25; strip twist 0.381; camber 0.1. Upset height is to be measured via section F-F direction. The dimensions shown represent the lead frame shape after stamping but before coining operation of coined area. The burr requirement after stamping includes: coin area vertical burr free; vertical burr maximum 0.025; horizontal burr maximum 0.05; burr up.

The conductive mounting platform 10A includes at least one indentation or notch structure in the exterior conductive surface, as described above with reference to FIG. 2. The indentation is a notch, recess, or step in a portion of an edge of the conductive mounting platform. The indentation receives or engages a portion of the package enclosure and secures the enclosure to the platform. The conductive mounting platform 10A may include an indentation in a portion or region of three the external edges of the conductive mounting platform 10A, but is not so limited. Thus, various alternative embodiments may include the indentation in portions or all of one or more edges of the conductive mounting platform 10A as appropriate to the semiconductor design. As an example, an alternative embodiment may include indentations in less than an entire length of an external edge of the conductive mounting platform. The conductive mounting platform of another alternative embodiment may include indentations in some portion of two opposing edges of the conductive mounting platform.

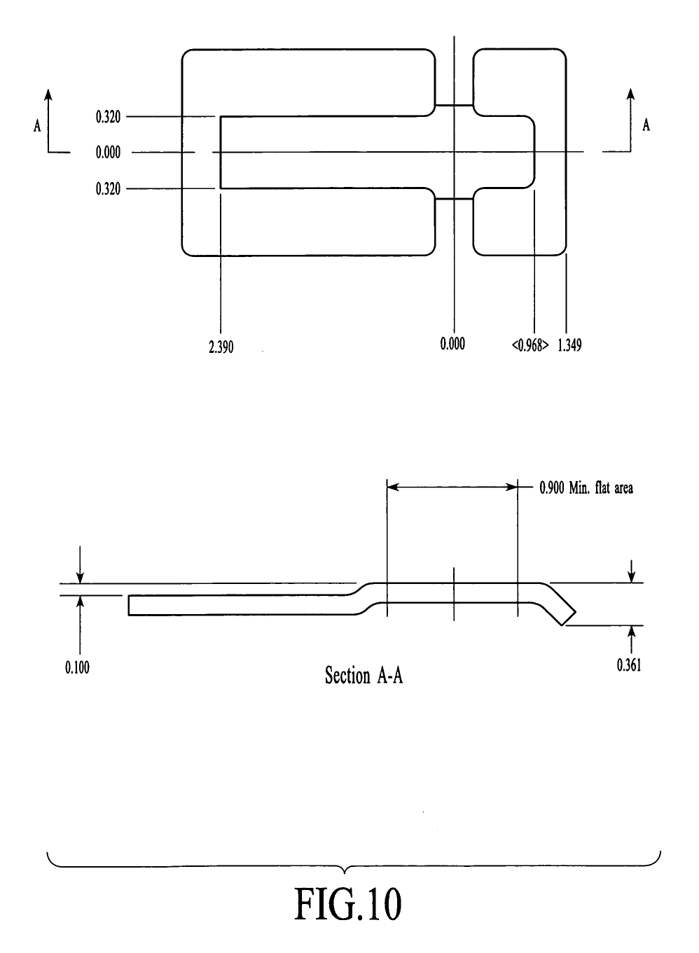

FIG. 10 is a detailed schematic diagram of a clip 40 having a dual clip configuration 40-3, under an embodiment. The dual clip configuration 40-3 is for use in a semiconductor device that includes conductive mounting platform 10A (FIG. 9), but is not so limited. The dimensions shown are in millimeters (mm). All tolerances are ±0.05 unless otherwise specified. The material is CDA 194FH, with thickness 0.152±0.008 mm. The twist over the strip length of the lead frame should not exceed 0.381. The camber over the strip length of the lead frame should not exceed 0.05. The coil-set over the strip length of the lead frame should not exceed 0.50. The crossbow over the width of the lead frame should not exceed 0.20. The vertical burr maximum is 0.03 mm. The horizontal burr maximum is 0.03.

Numerous semiconductor die may be used in the semiconductor device 500 that includes dual clips 40 having a dual clip configuration 40-3. As an example, the semiconductor device 500 may include a 108 mil dual anode die like the S9128K Schottky Die available from FabTech Incorporated.

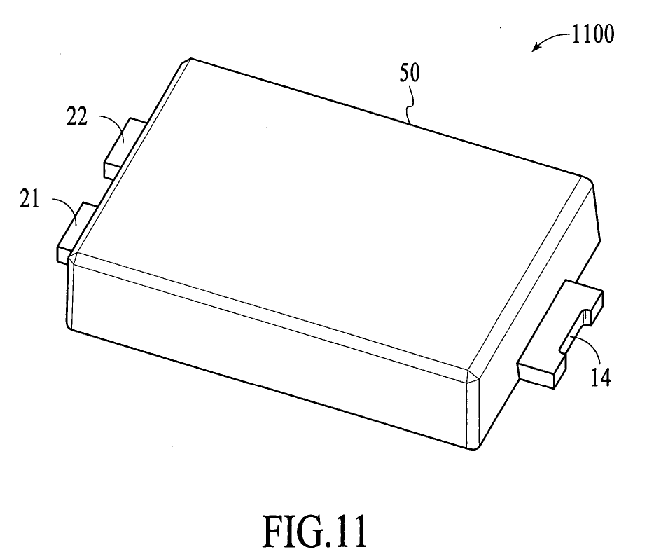

FIG. 11 is a schematic diagram of a semiconductor package 1100 including the semiconductor device 500 enclosed in a package enclosure 50, under an embodiment. The semiconductor package 1100 includes the package enclosure 50 formed around the semiconductor device 500 (FIG. 5) in such a manner as to engage the notches or indentations 17 (with reference to FIGS. 2, 4, and 9). The package enclosure 50 of an embodiment may be formed using materials that include Sumitomo EME-G700L series Green Compound for example, but is not so limited.

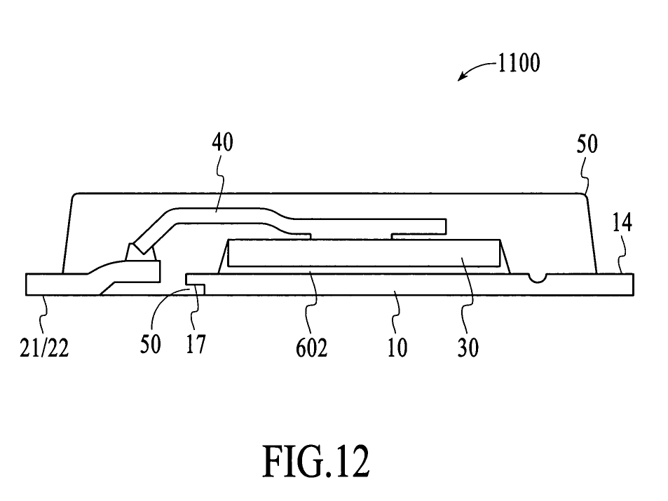

FIG. 12 is a cross-section of the semiconductor device 1100 including the semiconductor device 500, under an embodiment. The package enclosure 50 forms around the semiconductor device 500 in such a manner as to engage the notches or indentations 17 of the conductive mounting platform 10. The engaging or securing of the material of the package enclosure 50 in the notches 17 secures the package structure 50 to the conductive mounting platform 10.

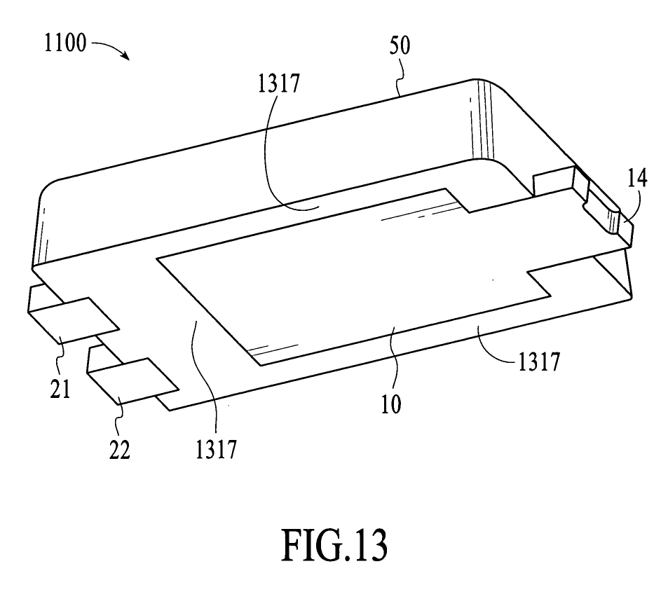

FIG. 13 is a bottom perspective view of the semiconductor package 1100 that includes the semiconductor device 500, under an embodiment. The package enclosure 50 forms around the semiconductor device 500 in such a manner as to engage the conductive mounting platform 10 in the area 1317 of the notches or indentations (not shown). The engaging or securing of the material of the package enclosure 50 in the area 1317 of the notches or indentations secures the package structure 50 to the conductive mounting platform 10.

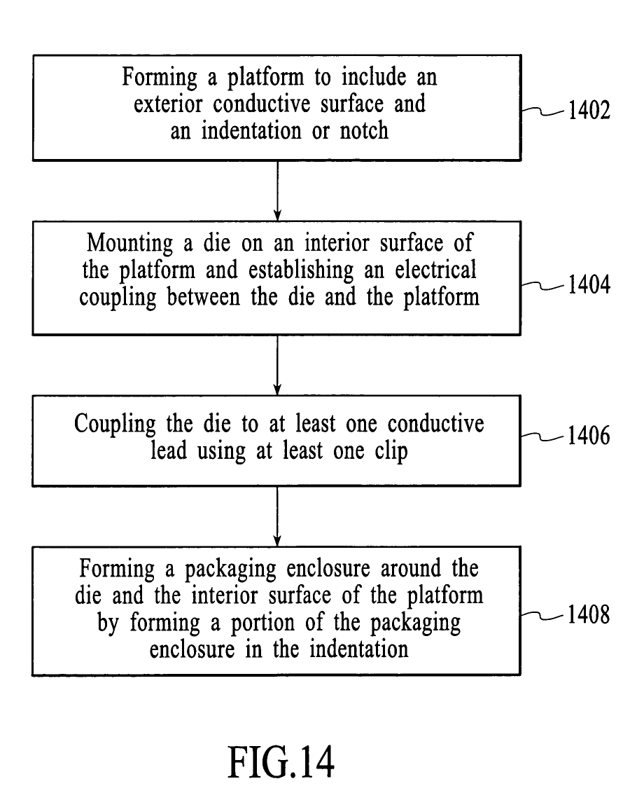

FIG. 14 is a flow diagram 1400 for manufacturing a semiconductor device, under an embodiment. This flow 1400 includes forming a platform to include an exterior conductive surface, at block 1402. The exterior conductive surface includes an indentation in at least one region of an edge of the exterior conductive surface, but is not so limited. The flow 1400 further includes mounting a die on an interior surface of the platform and establishing an electrical coupling between the die and the platform, at block 1404. Additionally, the flow 1400 includes coupling the die to at least one conductive lead using at least one clip, at block 1406. Furthermore, the flow 1400 includes forming a packaging enclosure around the die and the interior surface of the platform by forming a portion of the packaging enclosure in the indentation, at block 1408.

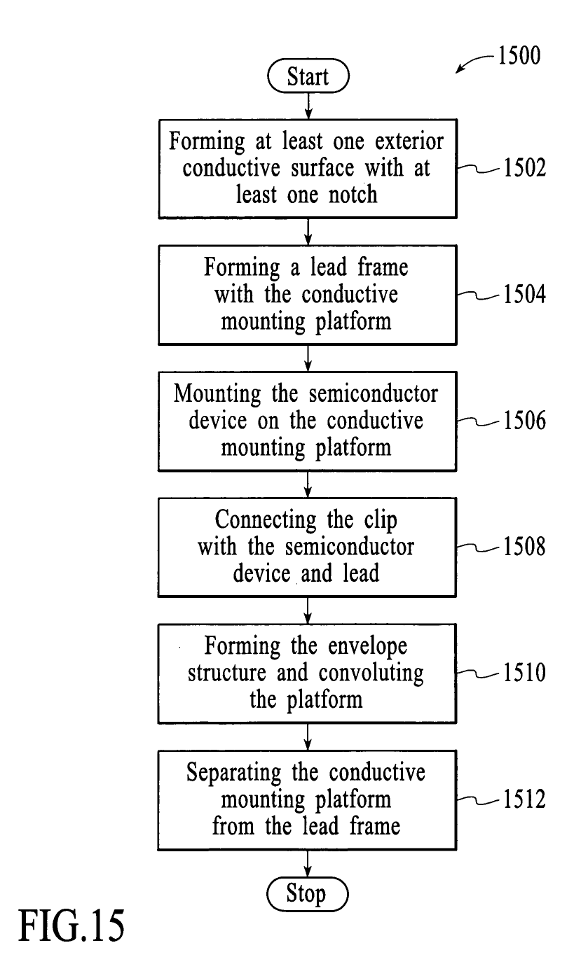

FIG. 15 is a flow diagram 1500 for manufacturing a semiconductor device, under an alternative embodiment. This flow 1500 includes forming at least one exterior conductive surface of a conductive platform to include at least one notch or indentation structure, at block 1502. The flow 1500 further includes forming a lead frame with the conductive mounting platform, at block 1504. The flow 1500 also includes mounting a semiconductor die on the conductive mounting platform so as to establish an electrical connection between the semiconductor die and the conductive mounting platform, at block 1506. Moreover, the flow 1500 includes connecting a clip to the semiconductor device through at least one contact surface of the conductive lead of the lead frame, at block 1508. The flow 1500 includes forming a packaging enclosure or structure around the semiconductor structure, at block 1510, so as to engage the notch structure of the conductive mounting platform. Additionally, the flow 1500 includes separating the conductive mounting platform from the lead frame, at block 1512, by separating the connecting element and conductive lead from the lead frame.

A semiconductor device support structure and package is described above that comprises a conductive mounting platform, a lead frame, a semiconductor die, and one or more clips. The conductive mounting platform includes a package envelope engaging element, an interior conductive surface, and an exterior or outer conductive surface. The package envelope engaging element of an embodiment includes at least one notch or indentation structure formed in at least one area of the outer conductive surface of the mounting platform, but is not so limited.

The lead frame includes a first side and a second side, and the conductive mounting platform is set between the first side and the second side of the lead frame. The first side of the lead frame includes at least one connecting element connected to one side of the conductive mounting platform. The second side of the lead frame includes at least one conductive lead extending from the second side of the lead frame and having a first end and a second end.

A semiconductor die is positioned on the interior conductive surface of the conductive mounting platform, and the semiconductor die includes a first electrical contact and a second electrical contact for respectively establishing electrical connections between the second electrical contact and the interior conductive surface of the conductive mounting platform. A clip is connected between the first end of the conductive lead and the first electrical contact of the semiconductor die.

Aspects of the semiconductor device support structures and the methods for making the same are described herein may be implemented as functionality programmed into any of a variety of circuitry, including programmable logic devices (PLDs), such as field programmable gate arrays (FPGAs), programmable array logic (PAL) devices, electrically programmable logic and memory devices and standard cell-based devices, as well as application specific integrated circuits (ASICs). Some other possibilities for implementing aspects of the semiconductor device support structures include: microcontrollers with memory (such as electronically erasable programmable read only memory (EEPROM)), embedded microprocessors, firmware, software, etc. Furthermore, aspects of the semiconductor device support structures may be embodied in microprocessors having software-based circuit emulation, discrete logic (sequential and combinatorial), custom devices, fuzzy (neural) logic, quantum devices, and hybrids of any of the above device types. Of course any underlying device technologies may be provided in a variety of component types, e.g., metal-oxide semiconductor field-effect transistor (MOSFET) technologies like complementary metal-oxide semiconductor (CMOS), bipolar technologies like emitter-coupled logic (ECL), polymer technologies (e.g., silicon-conjugated polymer and metal-conjugated polymer-metal structures), mixed analog and digital, etc.

It should be noted that the various processes and/or devices disclosed herein may be described using computer aided design tools and expressed (or represented), as data and/or instructions embodied in various computer-readable media, in terms of their behavioral, register transfer, logic component, transistor, layout geometries, and/or other characteristics. Formats of files and other objects in which such expressions may be implemented include, but are not limited to, formats supporting behavioral languages such as C, Verilog, and HLDL, formats supporting register level description languages like RTL, and formats supporting geometry description languages such as GDSII, GDSIII, GDSIV, CIF, MEBES and any other suitable formats and languages. Computer-readable media in which such formatted data and/or instructions may be embodied include, but are not limited to, non-volatile storage media in various forms (e.g., optical, magnetic or semiconductor storage media) and carrier waves that may be used to transfer such formatted data and/or instructions through wireless, optical, or wired signaling media or any combination thereof. Examples of transfers of such formatted data and/or instructions by carrier waves include, but are not limited to, transfers (uploads, downloads, e-mail, etc.) over the Internet and/or other computer networks via one or more data transfer protocols (e.g., HTTP, FTP, SMTP, etc.).

When received within a computer system via one or more computer-readable media, such data and/or instruction-based expressions of the above described processes and/or devices may be processed by a processing entity (e.g., one or more processors) within the computer system in conjunction with execution of one or more other computer programs including, without limitation, netlist generation programs, place and route programs and the like, to generate a representation or image of a physical manifestation of such processes and/or devices. Such representation or image may thereafter be used in semiconductor device fabrication.

Unless the context clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list, all of the items in the list and any combination of the items in the list.

The above description of illustrated embodiments of the semiconductor device support structures are not intended to be exhaustive or to limit the processes and/or devices to the precise form disclosed. While specific embodiments of, and examples for, the semiconductor device support structures are described herein for illustrative purposes, various equivalent modifications are possible within the scope of these processes and/or devices, as those skilled in the relevant art will recognize. The teachings of the semiconductor device support structures provided herein can be applied to other processing systems and methods, not only for the systems and methods described above.

The elements and acts of the various embodiments described above can be combined to provide further embodiments. These and other changes can be made to the semiconductor device support structures in light of the above detailed description.

In general, in the following claims, the terms used should not be construed to limit the semiconductor device support structures to the specific embodiments disclosed in the specification and the claims, but should be construed to include all semiconductor devices and methods that operate under the claims. Accordingly, the semiconductor device support structures are not limited by the disclosure, but instead the scope of these devices and/or processes is to be determined entirely by the claims.

While certain aspects of the semiconductor device support structures are presented below in certain claim forms, the inventors contemplate the various aspects of these processes and/or devices in any number of claim forms. Accordingly, the inventors reserve the right to add additional claims after filing the application to pursue such additional claim forms for other aspects of the semiconductor device support structures.

1. A semiconductor device, comprising:
a platform that includes an interior surface and an exterior conductive surface;
an indentation in the exterior conductive surface, wherein the indentation is a notch in at least portion of at least one edge of the exterior conductive surface;
a die coupled to the interior surface of the platform;
at least one conductive lead and at least one clip that couples a conductive region of the die to the at least one conductive lead; and
an enclosure that connects to at least one area of the indentation to enclose the die and the interior surface of the platform.

2. The device of claim 1, wherein the indentation engages the enclosure and secures the enclosure to the platform.

3. The device of claim 1, wherein the at least one portion of at least one edge of the exterior conductive surface includes at least one portion of each of three exterior edges of the exterior conductive surface.

4. The device of claim 1, further comprising a lead frame that includes the platform and the at least one conductive lead.

5. The device of claim 4, further comprising a single connecting element that couples the platform to the lead frame.

6. The device of claim 4, wherein a thickness of the lead frame is approximately 15 mils.

7. The device of claim 1, wherein the at least one conductive lead includes one conductive lead and the at least one clip includes one clip that couples the conductive region of the die to the one conductive lead.

8. The device of claim 1, wherein the at least one conductive lead includes a first conductive lead and a second conductive lead, wherein the at least one clip includes a first clip and a second clip, wherein the first clip couples the conductive region of the die to the first conductive lead and the second clip couples the conductive region of the die to the second conductive lead.

9. A semiconductor device, comprising:
a platform that includes an interior surface and an exterior conductive surface, the exterior conductive surface including a notch in at least one region of an edge of the exterior conductive surface;
a semiconductor die coupled to the interior surface of the platform;
at least one conductive lead;
at least one clip that couples a region of the semiconductor die to the at least one conductive lead; and
a packaging enclosure that couples to at least one area of the notch to enclose the die and the interior surface of the platform.

10. The device of claim 9, wherein the at least one region of the edge of the exterior conductive surface includes a portion of the edge of the exterior conductive surface.

11. The device of claim 9, further comprising a lead frame that includes the platform and the at least one conductive lead.

12. The device of claim 11, further comprising a single connecting element that couples the platform to the lead frame.

13. The device of claim 11, wherein a thickness of the lead frame is approximately 15 mils.

14. The device of claim 9, wherein the at least one conductive lead includes one conductive lead and the at least one clip includes one clip that couples a conductive region of the semiconductor die to the one conductive lead.

15. The device of claim 9, wherein the at least one conductive lead includes a first conductive lead and a second conductive lead, wherein the at least one clip includes a first clip and a second clip, wherein the first clip couples a conductive region of the semiconductor die to the first conductive lead and the second clip couples the conductive region of the semiconductor die to the second conductive lead.

16. A method for manufacturing a semiconductor device, comprising:
forming a platform to include an exterior conductive surface, the exterior conductive surface including an indentation in at least one region of an edge of the exterior conductive surface;
mounting a die on an interior surface of the platform and establishing an electrical coupling between the die and the platform;
coupling the die to at least one conductive lead using at least one clip; and
forming a packaging enclosure around the die and the interior surface of the platform by forming a portion of the packaging enclosure in the indentation.

17. The method of claim 16, further comprising forming a lead frame that includes the platform and the at least one conductive lead.

18. The method of claim 17, further comprising forming a single connecting element that couples the platform to the lead frame.

19. The method of claim 17, wherein a thickness of the lead frame is approximately 15 mils.

20. The method of claim 17, further comprising separating the platform from the lead frame.

21. The method of claim 16, wherein the at least one region of an edge of the exterior conductive surface includes at least one region of a plurality of exterior edges of the exterior conductive surface.

22. The method of claim 16, wherein coupling the die to at least one conductive lead using at least one clip further includes coupling a first conductive lead to a conductive region of the die using a first clip.

23. The method of claim 22, wherein coupling the die to at least one conductive lead using at least one clip further includes coupling a second conductive lead to a conductive region of the die using a second clip.

24. The semiconductor device produced by the method of claim 16.

25. A semiconductor device comprising a platform, a die, and an enclosure, the semiconductor device formed by:
forming the platform to include an exterior conductive surface, the exterior conductive surface including an indentation in at least one region of an edge of the exterior conductive surface;
mounting the die on an interior surface of the platform and establishing an electrical coupling between the die and the platform;
coupling the die to at least one conductive lead using at least one clip; and
forming the enclosure around the die and the interior surface of the platform by forming a portion of the enclosure in the indentation.

26. The device of claim 25, wherein the semiconductor device is further formed by:
forming a lead frame that includes the platform and the at least one conductive lead; and
forming a single connecting element that couples the platform to the lead frame.

27. The device of claim 26, wherein a thickness of the lead frame is approximately 15 mils.

28. The device of claim 25, wherein the at least one region of an edge of the exterior conductive surface includes at least one region of a plurality of exterior edges of the exterior conductive surface.
